(19) United States
(12) Patent Application Publication
(10) Pub. No.: US 2016/0348238 A1
(43) Pub. Date: Dec. 1, 2016

(54) FILM FORMING APPARATUS

(71) Applicant: Kabushiki Kaisha Toshiba, Tokyo (JP)

(72) Inventors: Rempei Nakata, Kanazawa Ishikawa (JP); Kenichi Ootsuka, Yokkaichi Mie (JP); Yuuichi Kuroda, Yokkaichi Mie (JP); Masaki Hirano, Yokkaichi Mie (JP); Naoto Miyashita, Kanazawa Ishikawa (JP); Tsutomu Miki, Yokkaichi Mie (JP)

(21) Appl. No.: 15/012,003

(22) Filed: Feb. 1, 2016

(30) Foreign Application Priority Data
May 28, 2015 (JP) 2015-108792

(51) Int. Cl. C23C 16/44; H01L 21/02; C30B 29/06; C23C 16/24; C30B 25/14

(52) U.S. Cl. CPC C23C 16/4412; C23C 16/24; C30B 25/14; C30B 29/06; H01L 21/02532; H01L 21/0262

(57) ABSTRACT

A film forming apparatus according to an embodiment comprises a film forming chamber. A first pipe part is connected to the film forming chamber and leads a discharge gas out of the film forming chamber. The first pipe part has a first opening area in a cross-section perpendicular to a moving direction of the discharge gas. A liquid discharger discharges a part of the discharge gas liquefied in the first pipe part. A second pipe part is provided between the first pipe part and the liquid discharger and has a second opening area smaller than the first opening area in a cross-section perpendicular to a moving direction of the discharge gas.

### CROSS REFERENCE TO RELATED APPLICATIONS

This application is based upon and claims the benefit of priority from the prior Japanese Patent Application No. 2015-108792, filed on May 28, 2015, the entire contents of which are incorporated herein by reference.

### FIELD

The embodiments of the present invention relate to a film forming apparatus.

### BACKGROUND

A film forming apparatus used in a semiconductor manufacturing process, a liquid-crystal manufacturing process, or the like heats a substrate in a film forming chamber and supplies a source gas and the like into the film forming chamber to form a material film on the substrate. The source gas supplied into the film forming chamber reacts in the film forming chamber, thereby forming a material film on the substrate. The source gas not having been used in film formation and left in the film forming chamber and a discharge gas containing reaction residual products generated due to film formation reaction and the like are discharged from the film forming chamber to outside of the film forming chamber via a gas discharge pipe, a pump, a detoxifying apparatus, and the like.

However, in some cases, the discharge gas is cooled and condenses into a liquid while passing through the gas discharge pipe from the film forming chamber. In such cases, the liquid discharge gas may adhere to an inner wall of the gas discharge pipe to occlude the gas discharge pipe or may adhere to the inside of the gas discharge pump to cause a malfunction of the gas discharge pump.

If the gas discharge pipe is occluded or the gas discharge pump malfunctions, the gas discharge pipe or the gas discharge pump needs to be detached from the film forming apparatus and cleaned or repaired. However, some of sources used in film formation or reaction residual products may react with moisture in the air to cause a toxic gas or may contain a material that ignites. Therefore, an operation of replacing the gas discharge pipe or the gas discharge pump is quite hazardous.

### BRIEF DESCRIPTION OF THE DRAWINGS

FIG. 1 is a schematic diagram showing an example of a configuration of a film forming apparatus 100 according to a first embodiment;

FIG. 2 is a graph showing the capture amount of the liquefied discharge gas with respect to the integrated flow rate of the discharge gas;

FIG. 3 is a graph showing a relation between the ratio (S20/S10) of the opening area S20 of the accelerator 20 to the opening area S10 of the cooler 10 and the capturing rate of the droplets of the discharge gas;

FIGS. 4A and 4B are cross-sectional views showing examples of the configuration of the capturing part 30, respectively;

FIG. 5 is a schematic diagram showing an example of a configuration of a film forming apparatus 200 according to a second embodiment;

FIG. 6 is a schematic diagram showing an example of a configuration of a film forming apparatus 300 according to a third embodiment; and

FIG. 7 is a schematic diagram showing an example of a configuration of a film forming apparatus 400 according to a fourth embodiment.

### DETAILED DESCRIPTION

Embodiments will now be explained with reference to the accompanying drawings. The present invention is not limited to the embodiments.

A film forming apparatus according to an embodiment comprises a film forming chamber. A first pipe part is connected to the film forming chamber and leads a discharge gas out of the film forming chamber. The first pipe part has a first opening area in a cross-section perpendicular to a moving direction of the discharge gas. A liquid discharger discharges a part of the discharge gas liquefied in the first pipe part. A second pipe part is provided between the first pipe part and the liquid discharger and has a second opening area smaller than the first opening area in a cross-section perpendicular to a moving direction of the discharge gas.

### First Embodiment

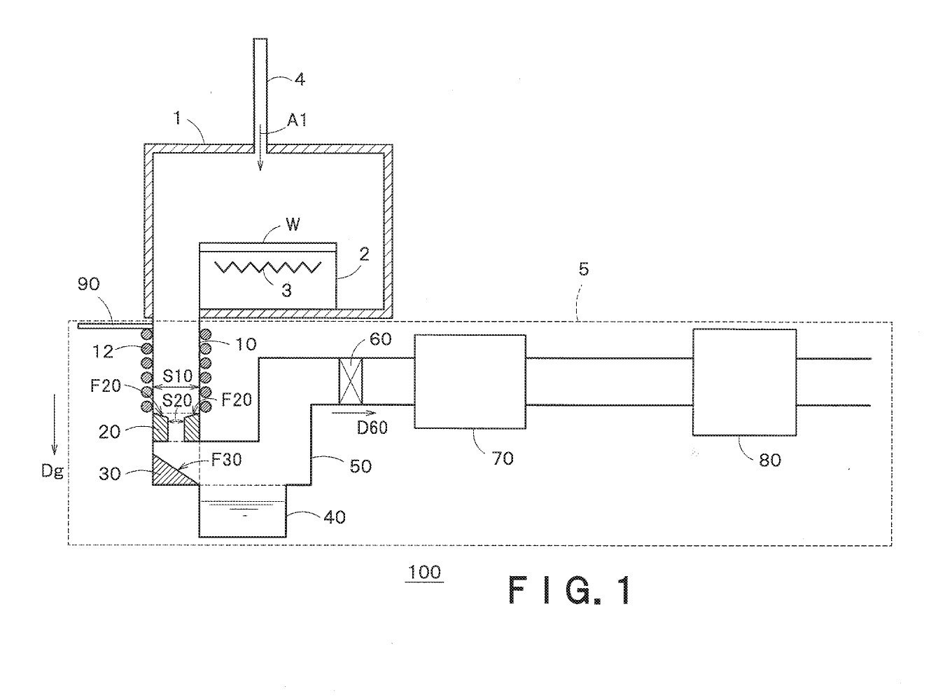

FIG. 1 is a schematic diagram showing an example of a configuration of a film forming apparatus 100 according to a first embodiment. The film forming apparatus 100 includes a film forming chamber 1, a stage 2, a heater 3, an introducing part 4, and a discharger 5.

The film forming apparatus 100 can be, for example, a semiconductor manufacturing apparatus such as a CVD (Chemical Vapor Deposition) apparatus or an epitaxial-film forming apparatus, or a liquid-crystal manufacturing apparatus. The film forming apparatus 100 forms a material film on a substrate W that is mounted on the stage 2 using a source gas introduced from the introducing part 4 in the film forming chamber 1.

The film forming chamber 1 has the stage 2 and the heater 3 incorporated therein and the pressure in the film forming chamber 1 is reduced during film forming processing. The stage 2 can have the substrate (a semiconductor wafer, for example) W mounted thereon and the heater 3 can heat the substrate W mounted on the stage 2. The introducing part 4 is a pipe connected to the film forming chamber 1 to introduce the source gas to be used in film formation into the film forming chamber 1.

The discharger 5 is connected to the film forming chamber 1 and discharges the source gas not having been used in film formation and remaining in the film forming chamber 1 and a reaction residual product gas (hereinafter also “discharge gas”) generated by the film forming processing from the film forming chamber 1. The discharger 5 includes a cooler (first pipe part) 10, a cooling tube 12, an accelerator (second pipe part) 20, a capturing part (first member) 30, a liquid discharger 40, a third pipe part 50, a pressure adjusting valve GO, a gas discharge pump 70, a detoxifying apparatus 80, and a cleaning-gas introducing pipe 90.

The cooler 10 serving as the first pipe part has one end connected to the film forming chamber 1 and the other end connected to the accelerator 20. The cooler 10 causes the discharge gas remaining in the film forming chamber 1 to pass from the film forming chamber 1 to the accelerator 20. At that time, the cooler 10 cools the discharge gas and condenses at least a part of the discharge gas into a liquid. In the first embodiment, the cooler 10 extends in a gravity direction (downward in a vertical direction) Dg to move the liquefied discharge gas in the gravity direction Dg.

The cooling tube 12 is spirally wound around the cooler 10 and causes a refrigerant to pass therethrough to cool the discharge gas. The refrigerant can be, for example, a medium such as water. The cooler 10 in the first embodiment is cooled by the refrigerant that passes through the cooling tube 12. However, the cooling tube 12 does not need to be provided. In this case, the cooler 10 cools (air-cools) the discharge gas through heat exchange between the discharge gas in the cooler 10 and the air outside thereof. That is, the cooler 10 can be provided simply as a pipe. It suffices to use a material highly resistant to corrosion such as stainless steel for the cooler 10 and the cooling tube 12.

The accelerator 20 serving as the second pipe part has one end connected to the cooler 10 and the other end connected to the capturing part 30. The accelerator 20 is communicated with the cooler 10 and is provided to extend in the gravity direction Dg. The accelerator 20 has a relatively small opening area to accelerate droplets of the discharge gas liquefied in the cooler 10 toward the capturing part 30. That is, the accelerator 20 has a smaller opening area in a cross-section perpendicular to a moving direction of the discharge gas than that of the cooler 10. For example, assuming that the opening area of the cooler 10 is a first opening area S10 and the opening area of the accelerator 20 is a second opening area S20, the second opening area S20 is smaller than the first opening area S10. Therefore, when the gas discharge pump 70 attempts to draw out (to suck in) the discharge gas, the discharge gas is accelerated while passing through the accelerator 20 from the cooler 10. In other words, the discharge gas present in the cooler 10 is accelerated in the accelerator 20 relatively small in the opening area due to an atmospheric pressure difference between the cooler 10 and the third pipe part 50. Accordingly, a moving speed (a flow rate) of the discharge gas in the accelerator 20 becomes larger than a moving speed (a flow rate) of the discharge gas in the cooler 10. Therefore, the droplets of the liquefied discharge gas are also accelerated together with the gaseous discharge gas in the accelerator 20 and move toward the capturing part 30. Because the accelerator 20 extends and opens in the gravity direction Dg as well as the cooler 10, the droplets of the discharge gas are accelerated not only by acceleration in the accelerator 20 but also by the gravity. The extending direction of the accelerator 20 can be inclined with respect to the gravity direction Dg or can be horizontal. In this case, the droplets of the discharge gas obtain a smaller acceleration effect of the gravity or cannot obtain the acceleration effect. However, the acceleration effect in the accelerator 20 can be still obtained.

The accelerator 20 has an inclined face F20 at an end portion on the side of the cooler 10. The inclined face F20 is provided to be inclined in the gravity direction Dg as approaching a central portion of the accelerator 20 from an outer edge of the accelerator 20. Accordingly, even when the liquefied discharge gas adheres to the inner wall of the cooler 10, the liquid of the discharge gas can run (flow) over the inclined face F20 down to the capturing part 30 that is located below the accelerator 20 without accumulating at the end portion of the accelerator 20 on the side of the cooler 10.

The capturing part 30 serving as a first member is provided between the accelerator 20 and the liquid discharger 40 and has a first face F30 facing in the moving direction of the discharge gas in the accelerator 20. Accordingly, the droplets of the discharge gas accelerated by the accelerator 20 hit the first face F30 of the capturing part 30 and adhere thereto. The first face F30 is inclined in the gravity direction Dg as approaching the liquid discharger 40.

That is, the first face F30 is inclined to cause the liquid to flow toward the liquid discharger 40. The droplets of the discharge gas having adhered to the first face F30 thereby flow to the liquid discharger 40 and are housed in the liquid discharger 40.

The liquid discharger 40 is a liquid discharge tank provided between the capturing part 30 and the third pipe part 50 and accumulates the liquid of the liquefied discharge gas therein. The liquid discharger 40 is provided on a downstream side of the cooler 10, the accelerator 20, and the capturing part 30 to collect the liquid of the discharge gas therein and is placed at a position lower than the cooler 10, the accelerator 20, and the capturing part 30, and the third pipe part 50 in the gravity direction Dg. This suppresses a back-flow of the droplets of the discharge gas from the liquid discharger 40 to the cooler 10, the accelerator 20, and the capturing part 30. An outflow of the droplets of the discharge gas from the liquid discharger 40 to the third pipe part 50 can be also suppressed.

The liquid discharger 40 can be a liquid discharge pipe (a liquid discharge drain) instead of the liquid discharge tank. In this case, it suffices that a liquid discharge tank is placed outside the film forming apparatus 100 and that the liquid discharger 40 serving as the liquid discharge pipe transports the liquid of the discharge gas to the liquid discharge tank. Furthermore, the liquid discharger 40 can be both a liquid discharge tank and a liquid discharge pipe. In this case, it suffices that the liquid discharger 40 temporarily accumulates the liquid of the discharge gas in the liquid discharge tank and then transports the liquid of the discharge gas to outside of the film forming apparatus 100 via the liquid discharge pipe.

The third pipe part 50 is located above the liquid discharger 40 and is communicated with the accelerator 20 via the capturing part 30. Accordingly, the gaseous discharge gas not liquefied passes above the liquid discharger 40 after having passed through the accelerator 20 to flow to the third pipe part 50. The third pipe part 50 is connected to the gas discharge pump 70 and the gaseous discharge gas having passed through the third pipe part 50 is caused to flow to the detoxifying apparatus 80 by the gas discharge pump 70.

The pressure adjusting valve 60 is provided in the third pipe part 50 and adjusts the opening degree of the third pipe part 50, thereby adjusting the atmospheric pressure in the film forming chamber 1. It suffices that a material resistant to the discharge gas, such as stainless steel is used for the accelerator 20, the capturing part 30, the liquid discharger 40, the third pipe part 50, and the pressure adjusting valve 60.

The gas discharge pump 70 is provided between the third pipe part 50 and the detoxifying apparatus 80 and is used to discharge the discharge gas and to perform vacuuming of the film forming chamber 1 to reduce the pressure therein.

Drawing of the discharge gas from the film forming chamber 1 by the gas discharge pump 70 enables the gaseous discharge gas and the droplets of the discharge gas to pass through the cooler 10 and to be accelerated by the accelerator 20.

The detoxifying apparatus 80 is connected to a downstream side of the gas discharge pump 70 and detoxifies the discharge gas.

The detoxifying apparatus 80 discharges the detoxified discharge gas to outside of the film forming apparatus 100.

The cleaning-gas introducing pipe 90 is connected between the film forming chamber 1 and the cooler 10 and enables a cleaning gas (a CIF₃ gas, for example) to flow to the cooler 10, the accelerator 20, and the capturing part 30.

An operation of the film forming apparatus 100 is explained next. A step of growing a silicon epitaxial layer on the substrate W is explained.

First, the substrate W is loaded on the stage 2. The film forming chamber 1 is vacuumed using the gas discharge pump 70 to bring the inside of the film forming chamber 1 to a reduced pressure state. While a hydrogen gas is being supplied to the film forming chamber 1, the pressure in the film forming chamber 1 is controlled by the pressure adjusting valve 60. The substrate W is heated by the heater 3 up to the temperature of, for example, about 1000° C.

Next, the introducing part 4 causes a dichlorosilane (SiH₂Cl₂) gas, a hydrogen (H₂) gas, and a hydrogen chloride (HCl) gas to flow as source gases to grow a silicon epitaxial film on the substrate W. At that time, gases of chlorosilane monomers such as trichlorosilane (SiHCl₃) and tetrachlorosilane (SiCl₄), gases of chiorosilane polymers (SixHyClz: x is 2 or more) such as tetrachlorodisilane (Si₂H₂O₄), hexachlorodisilane (Si₂Cl₆), and octachlorotrisilane (Si₃Cl₈), and the like are generated as reaction residual products. The source gases not having been used for film formation also remain in the film forming chamber 1.

Therefore, dichlorosilane monomers and polymers are also contained in the discharge gas.

The gases of reaction residual products and the source gases need to be discharged from the film forming chamber 1. As the molecular weights of the reaction residual products and the source gases are larger, the boiling points are higher. For example, the boiling point of dichlorosilane as the source gas is about 8° C. while the boiling point of trichlorosilane is about 31° C. and the boiling point of tetrachlorosilane is about 57° C. Therefore, trichlorosilane and tetrachlorosilane are more likely to condense. Further, for example, chlorosilane polymers have a higher boiling point than that of chiorosilane monomers (that can contain chlorosilane polymers having smaller molecular weights) and are more likely to condense. Therefore, when the discharge gas moves to the cooler 10 and is cooled, gases of chiorosilane polymers condense to a liquid and float in the cooler 10 as droplets having large particle sizes or adhere to the inner wall of the cooler 10. Also the chlorosilane monomers having a relatively low boiling point can condense to droplets when cooled in the cooler 10. The cooling tube 12 causes, for example, water at about 10° C. as the refrigerant to flow therethrough. Because dichlorosilane as the source gas has a relatively low boiling point, a part of dichlorosilane can pass through the cooler 10 as the gas, which is discharged through the gas discharge pump 70 and the detoxifying apparatus 80.

The discharge gas cooled in the cooler 10 is accelerated in the accelerator 20 in a discharge direction (the same direction as the gravity direction Dg in this example). At that time, the droplets of the chlorosilane monomers and the droplets of the chlorosilane polymers are accelerated together with the gaseous discharge gas and move toward the first face F30 of the capturing part 30. The liquid of the discharge gas having adhered to the inner wall of the cooler 10 flows down in the gravity direction Dg. Because the accelerator 20 has the inclined face F20, the liquid of the discharge gas can flow down toward the capturing part 30 along the inclined face F20 without accumulating at the end portion of the accelerator 20.

Liquids of high-molecular chlorosilane polymers have a relatively high viscosity and are less likely to flow when having adhered to a wall surface. However, liquids of low-molecular chlorosilane polymers or liquids of chlorosilane monomers have a relatively low viscosity and are likely to flow when having simultaneously adhered to the wall surface. In the first embodiment, not only the gases of the chlorosilane polymers but also the gases of the chlorosilane monomers are also liquefied by cooling of the discharge gas in the cooler 10. Therefore, the liquids of the chlorosilane polymers and monomers having a low viscosity as well as the liquids of the chlorosilane polymers having a high viscosity adhere to the inner wall of the cooler 10 and thus the liquid of the discharge gas can easily flow along the inner wall of the cooler 10 or the inclined face F20 of the accelerator 20. As a result, the liquid of the discharge gas is likely to be captured and the cooler 10, the accelerator 20, the gas discharge pump 70, and the like are less likely to be occluded.

The droplets of the chlorosilane monomers and the droplets of the chlorosilane polymers accelerated toward the first face F30 of the capturing part 30 thereafter hit the first face F30 and adhere thereto. The droplets having adhered to the first face F30 flow into the liquid discharger 40 along the inclination of the first face F30.

The liquid discharger 40 accumulates the liquefied discharge gas containing the chlorosilane monomers and the chlorosilane polymers therein or transports the liquefied discharge gas to outside of the film forming apparatus 100.

The discharge gas remaining as the gas is transported by the gas discharge pump 70 from the capturing part 30 to the detoxifying apparatus 80 via the third pipe part 50. The gaseous discharge gas is detoxified by the detoxifying apparatus 80 and is discharged to outside of the film forming apparatus 100.

As described above, the film forming apparatus 100 according to the first embodiment includes the accelerator 20 between the cooler 10 and the liquid discharger 40. The opening area (the opening area in the cross-section perpendicular to the moving direction of the discharge gas (the gravity direction Dg)) S20 of the accelerator 20 is smaller than the opening area S10 of the cooler 10. Accordingly, the accelerator 20 can accelerates the droplets generated due to condensation of the discharge gas in the moving direction of the discharge gas (the gravity direction Dg) and can hit the droplets on the capturing part 30. As a result, the film forming apparatus 100 can cause the droplets of the discharge gas (the droplets of the chlorosilane monomers and the chlorosilane polymers, for example) to adhere to the capturing part 30 more reliably and can cause the droplets to flow to the liquid discharger 40 more reliably. That is, the film forming apparatus 100 can separate between the droplets of the discharge gas and the gaseous discharge gas and discharge the droplets of the discharge gas to the liquid discharger 40 while discharging the gaseous discharge gas via the gas discharge pump 70 after being detoxified in the detoxifying apparatus 80.

If the cooler 10, the accelerator 20, the capturing part 30, and the liquid discharger 40 are not provided, the droplets of the discharge gas enter the third pipe part 50 and the gas discharge pump 70 while floating in the gaseous discharge gas. In this case, the droplets of the discharge gas may adhere to the pressure adjusting valve 60 or the gas discharge pump 70 and occlude the pressure adjusting valve 60 or the gas discharge pump 70.

On the other hand, according to the first embodiment, the film forming apparatus 100 can separate between the droplets of the discharge gas and the gaseous discharge gas and discharge the droplets of the discharge gas and the gaseous discharge gas separately. Therefore, an occlusion of the pressure adjusting valve 60 or the gas discharge pump 70 with the droplets of the discharge gas can be suppressed. This can remove the liquefied discharge gas efficiently and safely and can suppress an occlusion or a malfunction of a gas discharge pipe or a gas discharge pump.

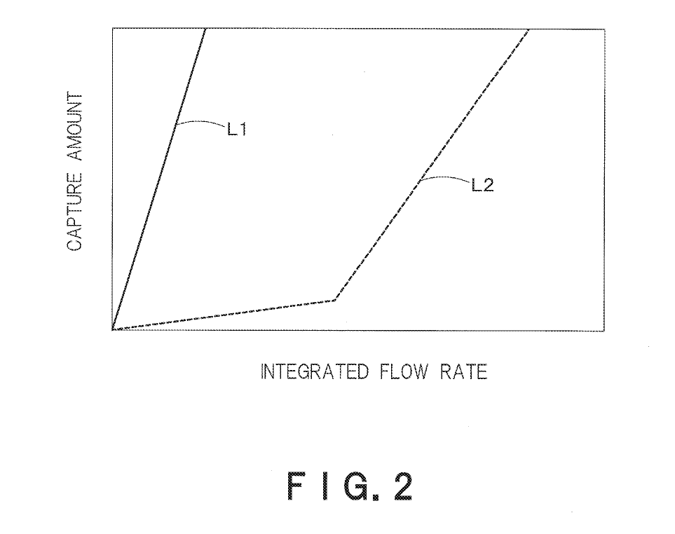

If the cooler 10 and the liquid discharger 40 are provided and the accelerator 20 and the capturing part 30 are not provided, most of the droplets of the discharge gas still enter the third pipe part 50 and the gas discharge pump 70 while floating in the gaseous discharge gas. For example, FIG. 2 is a graph showing the capture amount of the liquefied discharge gas with respect to the integrated flow rate of the discharge gas. A line L1 indicates the capture amount of the film forming apparatus 100 according to the first embodiment. A line L2 indicates the capture amount of a film forming apparatus that includes the cooler 10 and the liquid discharger 40 and does not include the accelerator 20 and the capturing part 30.

With reference to the line L2, the film forming apparatus not including the accelerator 20 and the capturing part 30 can capture only a small amount of the liquefied discharge gas when the integrated flow rate of the discharge gas is low. In this case, when the integrated flow rate of the discharge gas is low, the liquefied discharge gas keeps adhering to the inner wall of the cooler 10 and does not flow. When the integrated flow rate of the discharge gas thereafter becomes high, the liquefied discharge gas flows out of the inner wall of the cooler 10 and the capture amount of the liquefied discharge gas becomes large. Accordingly, the inclination of the line L2 changes in two steps.

On the other hand, the line L1 indicates that the film forming apparatus 100 according to the first embodiment can capture a large amount of the liquefied discharge gas regardless of the flow rate of the discharge gas. In this way, according to the first embodiment, because the accelerator 20 accelerates the droplets of the discharge gas and the capturing part 30 captures these droplets in a concentrated manner, the liquefied discharge gas can be removed more efficiently.

The end portion of the accelerator 20 on the side of the cooler 10 has the inclined face F20. This facilitates flow of the droplets of the discharge gas having adhered to the inner wall of the cooler 10 toward the capturing part 30. The capturing part 30 has the first face F30 inclined toward the liquid discharger 40. This facilitates flow of the droplets of the discharge gas toward the liquid discharger 40. The liquid discharger 40 is placed in a downward direction (the gravity direction Dg) relative to the cooler 10, the accelerator 20, the capturing part 30, and the third pipe part 50. Therefore, a back-flow of the liquid of the discharge gas having flowed in the liquid discharger 40 and the flow thereof into the side of the gas discharge pump 70 can be suppressed. Combination with the cleaning-gas introducing pipe 90 that introduces the cleaning gas can further enhance the effect of suppressing an occlusion of the pipe part and the gas discharge pump 70 in the discharger 5.

### (Consideration on Opening Area S20 of Accelerator 20)

The opening area S20 of the accelerator 20 is considered next.

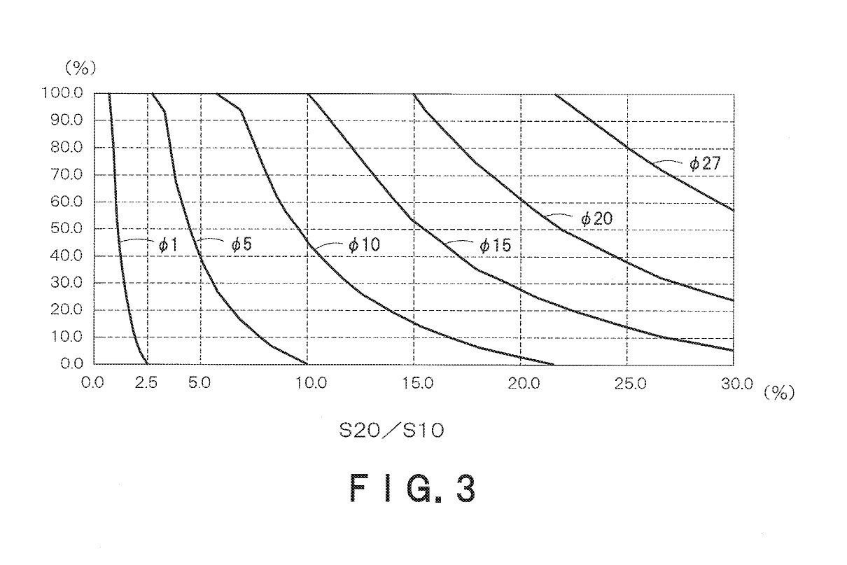

FIG. 3 is a graph showing a relation between the ratio (S20/S10) of the opening area S20 of the accelerator 20 to the opening area S10 of the cooler 10 and the capturing rate of the droplets of the discharge gas. The horizontal axis represents the ratio (S20/S10) of the opening area S20 of the accelerator 20 to the opening area S10 of the cooler 10. The vertical axis represents the capturing rate of the droplets of the discharge gas. A line ø1 shows the capturing rate in a case where the particle size (the diameter) of the droplets of the discharge gas is about 1 micrometer. A line ø5 shows the capturing rate in a case where the particle size (the diameter) of the droplets of the discharge gas is about 5 micrometers. A line ø10 shows the capturing rate in a case where the particle size (the diameter) of the droplets of the discharge gas is about 10 micrometers. A line ø15 shows the capturing rate in a case where the particle size (the diameter) of the droplets of the discharge gas is about 15 micrometers. A line ø20 shows the capturing rate in a case where the particle size (the diameter) of the droplets of the discharge gas is about 20 micrometer's. A line ø27 shows the capturing rate in a case where the particle size (the diameter) of the droplets of the discharge gas is about 27 micrometers.

The opening diameter of the cooler 10 used in this experiment was about 5 centimeters and the opening area S10 was about 2.5²n cm². The atmospheric pressure in the film forming chamber 1 was about 8 kilopascals and the flow rate of the gas introduced from the introducing part 4 was about 20 liters/minute. The density of the droplets of the discharge gas (Si₂Cl₆) was about 1.56 kilograms/liter.

When the ratio S20/S10 of the opening area exceeds about 20%, the capturing rate of the droplets having the particle sizes equal to or smaller than 10 micrometers is almost 0%. That is, when the opening area S20 of the accelerator 20 exceeds (2.5²n/5) cm², the discharger 5 can hardly capture the droplets having the particle sizes equal to or smaller than 10 micrometers. Therefore, to effectively capture the droplets having the particle sizes equal to or smaller than 10 micrometers, the ratio S20/S10 of the opening area is preferably equal to or lower than about 20%. That is, the opening area S20 of the accelerator 20 is preferably equal to or smaller than about (2.5²n/5) cm².

When the ratio S20/S10 of the opening area exceeds about 10%, the capturing rate of the droplets having the particle sizes equal to or smaller than 5 micrometers is almost 0%. That is, when the opening area S20 of the accelerator 20 exceeds (2.5²n/10) cm², the discharger 5 can hardly capture the droplets having the particle sizes equal to or smaller than 5 micrometers. Therefore, to effectively capture the droplets of the particle sizes equal to or smaller than 5 micrometers, it is more preferable that the ratio S20/S10 of the opening area is equal to or lower than about 10%. That is, it can be said that the opening area S20 of the accelerator 20 is more preferably equal to or smaller than about (2.5²n/10) cm².

When the ratio S20/S10 of the opening area is set to about 2.5% or lower, the discharger 5 can capture almost 100% of the droplets having the particle sizes equal to or larger than 5 micrometers. Therefore, the ratio S20/S10 of the opening area is further preferably equal to or lower than about 2.5%. That is, it is further preferable that the opening area S20 of the accelerator 20 is equal to or smaller than about (2.5²n/25) cm².

However, if the opening area S20 is too small, the atmospheric pressure in the film forming chamber 1 cannot be controlled. Or it takes a longer time for the gas discharge pump 70 to vacuum the film forming chamber 1. Therefore, to enhance the capturing rate of the droplets within a range in which the atmospheric pressure in the film forming chamber 1 can be controlled, the ratio S20/S10 of the opening area is preferably within a range between 2.5% and 20%. Because the droplets having the particle sizes smaller than 1 micrometer substantially do not have an adverse effect on the pipe part or the gas discharge pump 70, the ratio S20/S10 of the opening area can be set within the range between 2.5% and 20%. The droplets having the particle sizes smaller than 1 micrometer can be sufficiently removed by cleaning using the cleaning-gas introducing pipe 90. The particle sizes of the droplets of the discharge gas change depending on film forming conditions such as the film forming temperature, the pressure in the film forming chamber 1, and the gas flow rate. The range in which the atmospheric pressure in the film forming chamber 1 can be controlled changes depending on the gas discharge speed of the gas discharge pump 70 and the conductance of other pipe parts as well as the opening area S20 of the accelerator 20.

It is also preferable that the opening area S20 of the accelerator 20 is smaller than an opening area of the pressure adjusting valve 60. The opening area of the pressure adjusting valve 60 is an opening area in a cross-section perpendicular to a moving direction D60 of the discharge gas in the pressure adjusting valve 60 or the third pipe part 50.

When the accelerator 20 has a plurality of nozzles, the opening area S20 is the sum of opening areas of the nozzles.

### (Consideration on Capturing Part 30)

The configuration of the capturing part 30 is considered next.

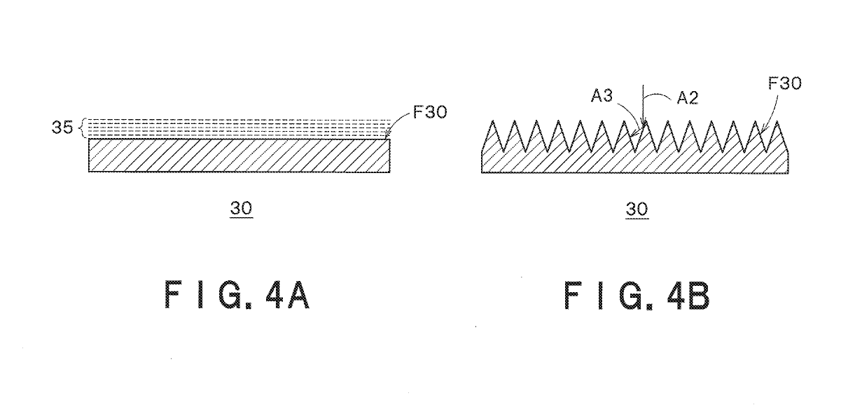

FIGS. 4A and 4B are cross-sectional views showing examples of the configuration of the capturing part 30, respectively. The droplets of the discharge gas hit the first face F30 of the capturing part 30 serving as the first member. At that time, some of the droplets of the discharge gas bounce back from the surface of the first face F30 due to impact of the hit. When the droplets of the discharge gas bounce back and spatter, there are cases where the droplets of the discharge gas are not captured by the first face F30 and adhere to pipes around the first face F30. To suppress such bouncing-hack or spattering of the droplets of the discharge gas, a mesh material 35 can be provided as a bouncing prevention material on the first face F30 of the capturing part 30 as shown in FIG. 4A. The mesh material 35 can be, for example, a single-layer or multi-layer stainless cloth. The mesh material 35 can absorb the droplets of the discharge gas coming toward the first face F30 due to a capillary phenomenon and suppress bouncing-back of the droplets of the discharge gas on the first face F30. That is, the mesh material 35 reduces the impact caused by the hit of the droplets and functions as a cushioning material. Therefore, the capturing part 30 can capture the droplets of the discharge gas more reliably.

Alternatively, to suppress bouncing-back of the droplets of the discharge gas, the first face F30 of the capturing part 30 can be formed in a serrated manner (in a concave-convex manner) and can have grooves as shown in FIG. 4B. To cause the liquid of the discharge gas to flow along the grooves into the liquid discharger 40, the grooves extend in a direction toward the liquid discharger 40. That is, the cross-section shown in FIG. 4B is a cross-section perpendicular to a direction from the capturing part 30 toward the liquid discharger 40. Due to the grooves provided on the first face F30, the droplets hit inclined faces of the grooves. Therefore, a direction in which the droplets bounce is a reflection direction A3 to an entering direction A2 of the droplets. Accordingly, even when the droplets bounce, the droplets bounce from the inclined faces of the grooves toward other inclined faces. As a result, spattering of the droplets of the discharge gas to parts other than the first face F30 can be suppressed and the capturing part 30 can capture the droplets of the discharge gas more reliably. Because the grooves extend in the direction toward the liquid discharger 40, the liquid of the discharge gas can easily flow along the grooves to the liquid discharger 40.

### Second Embodiment

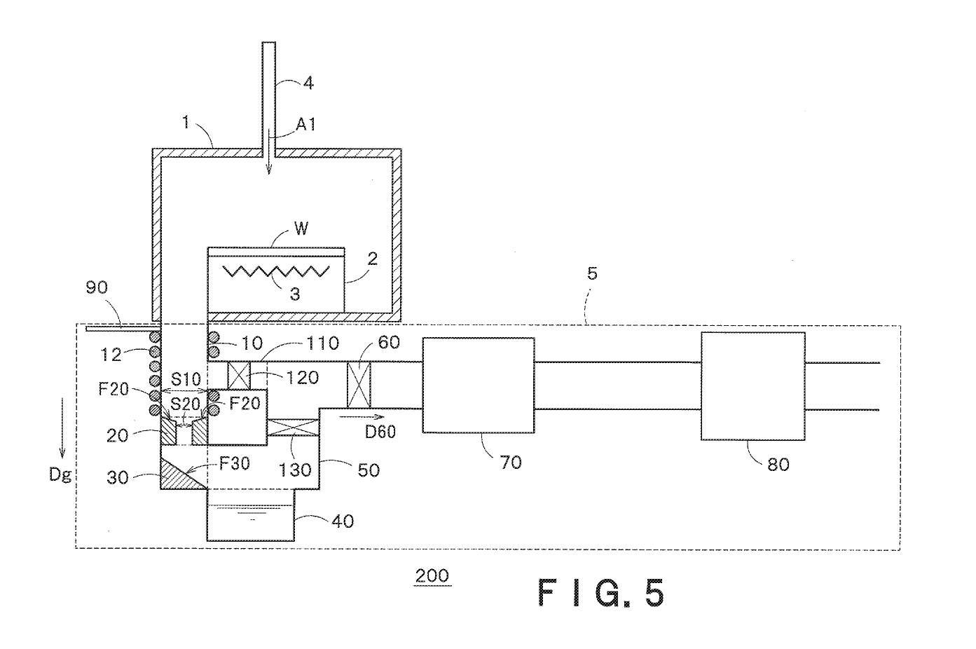

FIG. 5 is a schematic diagram showing an example of a configuration of a film forming apparatus 200 according to a second embodiment. The film forming apparatus 200 according to the second embodiment further includes a fourth pipe part 110, a first valve 120, and a second valve 130. One end of the fourth pipe part 110 is connected between the cooler 10 and the accelerator 20 and the other end thereof is connected to the third pipe part 50. That is, the fourth pipe part 110 connects between the cooler 10 and the third pipe part 50 not via the accelerator 20 and the capturing part 30. An opening area of the fourth pipe part 110 in a cross-section perpendicular to the moving direction of the discharge gas is larger than the opening area S20 of the accelerator 20. For example, the opening area of the fourth pipe part 110 can be equal to the opening area S10 of the cooler 10. The first valve 120 is provided in the fourth pipe part 110 and can open or close the fourth pipe part 110. The second valve 130 is provided at any position between the accelerator 20 and the third pipe part 50 and can open or close between the accelerator 20 and the third pipe part 50. The first and second valves 120 and 130 are controlled by a controller (not shown). Other configurations in the second embodiment can be identical to the corresponding ones in the first embodiment.

When the pressure in the film forming chamber 1 is to be reduced before the film forming processing is performed in the film forming chamber 1, the first valve 120 is opened. Due to opening of the first valve 120, the cooler 10 is directly connected to the third pipe part 50 via the fourth pipe part 110 not via the accelerator 20 and the capturing part 30. In this way, the fourth pipe part 110 can form an alternative path (a bypass) between the cooler 10 and the third pipe part 50. The alternative path through the fourth pipe part 110 is used when vacuuming is performed to reduce the pressure in the film forming chamber 1. Because the opening area of the fourth pipe part 110 is larger than the opening area S20 of the accelerator 20, the discharger 5 can rapidly reduce the pressure in the film forming chamber 1 using the alternative path through the fourth pipe part 110 even when the opening area S20 of the accelerator 20 is small. At that time, the second valve 130 can be closed or opened. When the second valve 130 is opened together with the first valve 120, the air can be discharged from both the first and second valves 120 and 130 and thus the pressure reduction speed can be further increased.

On the other hand, when the film forming processing is performed in the film forming chamber 1 and the discharge gas is to be discharged, the first valve 120 is closed and the second valve 130 is opened. The discharger 5 thereby has an identical configuration to that of the film forming apparatus 100 according to the first embodiment and the discharge gas is subjected to the gas discharging processing or the liquid discharging processing through the accelerator 20 and the capturing part 30.

If the fourth pipe part 110 is not provided and the opening area S20 of the accelerator 20 is set to be small to enhance the capturing effect on the droplets of the discharge gas, the gas discharge speed may be lowered due to the accelerator 20 and it may take a long time to reduce the atmospheric pressure in the film forming chamber 1 to a desired level.

In the second embodiment, the fourth pipe part 110 is thus provided between the cooler 10 and the third pipe part 50. Accordingly, when the pressure in the film forming chamber 1 is to be reduced, the first valve 120 is opened and the alternative path through the fourth pipe part 110 is used, whereby the pressure in the film forming chamber 1 can be rapidly reduced.

On the other hand, while the film forming processing is performed, the first valve 120 is closed and the second valve 130 is opened, whereby the accelerator 20 and the capturing part 30 can capture the droplets of the discharge gas efficiently. Therefore, the second embodiment can reduce the pressure in the film forming chamber 1 rapidly, and the second embodiment can obtain effects identical to those of the first embodiment.

### Third Embodiment

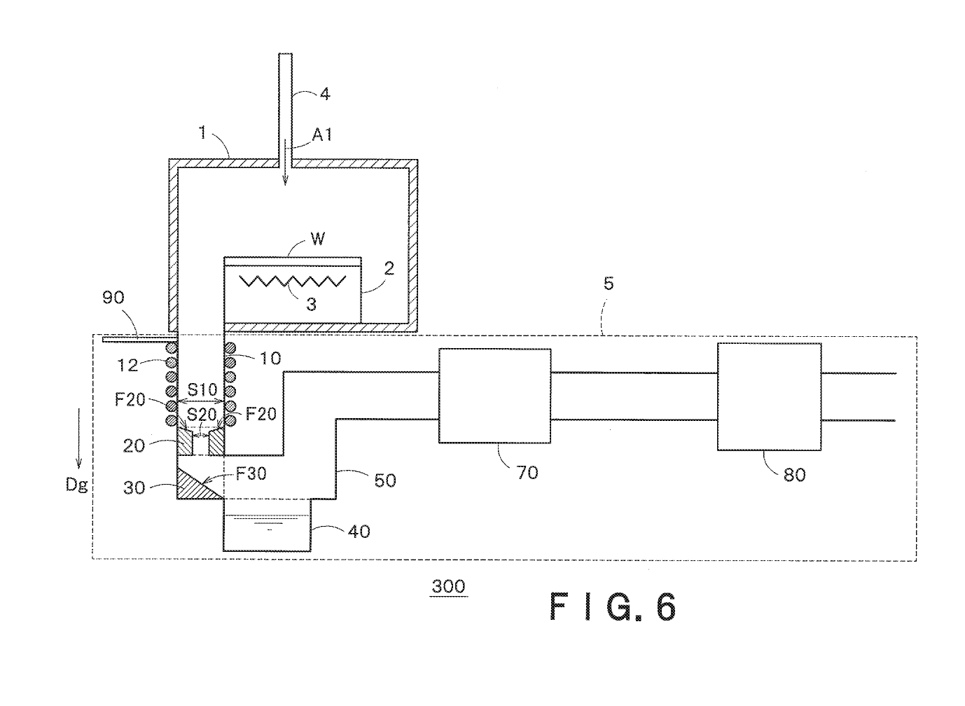

FIG. 6 is a schematic diagram showing an example of a configuration of a film forming apparatus 300 according to a third embodiment. The film forming apparatus 300 according to the third embodiment is different from the film forming apparatus 100 according to the first embodiment in that the accelerator 20 has also a pressure adjusting function and that the pressure adjusting valve 60 is omitted. Other configurations in the third embodiment can be identical to the corresponding ones in the first embodiment.

To provide the accelerator 20 with both the function of accelerating the droplets of the discharge gas and the function of adjusting the pressure, it is preferable that the opening area S20 of the accelerator 20 is variable. To cause the opening area S20 to be variable, the accelerator 20 can be implemented using a shutter mechanism, for example.

When the pressure in the film forming chamber 1 is to be reduced, the opening area S20 of the accelerator 20 is set to be relatively large. Accordingly, the gas discharge pump 70 can rapidly reduce the pressure in the film forming chamber 1. On the other hand, when the film forming processing is performed and the discharge gas is to be discharged, the opening area S20 of the accelerator 20 is set to be relatively small. This enables the accelerator 20 and the capturing part 30 to efficiently capture the droplets of the discharge gas.

As described above, in the third embodiment, assuming that the opening area S20 of the accelerator 20 during reduction of the pressure in the film forming chamber 1 is a first area and that the opening area S20 of the accelerator 20 during discharge of the discharge gas is a second area, the second area can be set to be smaller than the first area. Accordingly, the third embodiment can rapidly reduce the pressure in the film forming chamber 1 similarly to the second embodiment and obtain effects identical to those in the first embodiment.

Furthermore, because there is no pressure loss due to the pressure adjusting valve 60, the atmospheric pressure in the film forming chamber 1 can be controlled even when the opening area S20 of the accelerator 20 is set to be small. This enables the discharger 5 to capture the droplets of small particle sizes (equal to or smaller than 1 micrometer, for example) at a higher capturing rate. Because there is no need to provide the pressure adjusting valve 60, the size of the discharger 5 is reduced.

Even when the opening area S20 is variable, it is preferable that the accelerator 20 has the inclined face F20 at the end portion on the side of the cooler 10. With this configuration, the liquefied discharge gas can flow along the inclined face F20 down to the capturing part 30 that is located below the accelerator 20.

### Fourth Embodiment

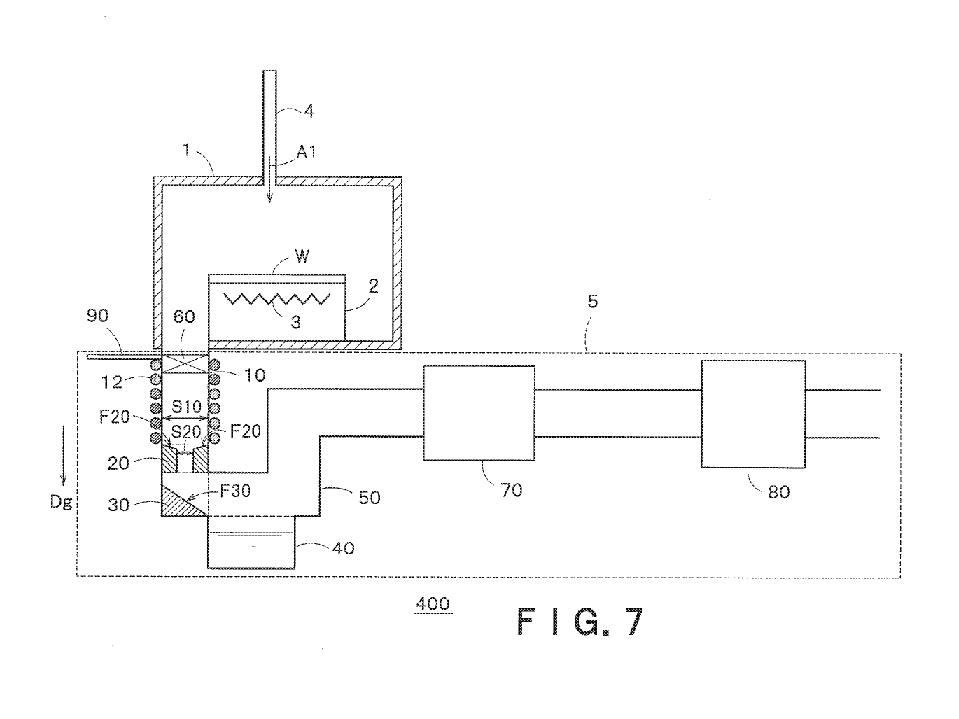

FIG. 7 is a schematic diagram showing an example of a configuration of a film forming apparatus 400 according to a fourth embodiment. In the film forming apparatus 400 according to the fourth embodiment, the pressure adjusting valve 60 is provided in the cooler 10 or between the film forming chamber 1 and the cooler 10. Other configurations in the fourth embodiment can be identical to the corresponding ones in the first embodiment. Thus, even if the pressure adjusting valve 60 is located upstream of the accelerator 20, the effects of the embodiment are not degraded.

The discharger 5 according to the above embodiments is applicable to a polysilicon-film forming apparatus, an etching apparatus, and a liquid-crystal manufacturing apparatus, as well as an epitaxial-film forming apparatus.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A film forming apparatus comprising:
a film forming chamber;
a first pipe part connected to the film forming chamber and leading a discharge gas out of the film forming chamber, the first pipe part having a first opening area in a cross-section perpendicular to a discharging direction of the discharge gas;
a liquid discharger discharging a part of the discharge gas liquefied in the first pipe part; and
a second pipe part provided between the first pipe part and the liquid discharger and having a second opening area smaller than the first opening area in a cross-section perpendicular to a discharging direction of the discharge gas.

2. The apparatus of claim 1, wherein an end portion of the second pipe part on a side of the first pipe part is inclined in a gravity direction as approaching from an outer edge of the second pipe part toward a central portion of the second pipe part.

3. The apparatus of claim 1, further comprising a cooling tube provided around the first pipe part and causing a refrigerant to pass therethrough.

4. The apparatus of claim 2, further comprising a cooling tube provided around the first pipe part and causing a refrigerant to pass therethrough.

5. The apparatus of claim 1, wherein the liquid discharger is a liquid discharge tank or a liquid discharge pipe located at a position lower than the first and second pipe parts.

6. The apparatus of claim 1, wherein a moving speed of reaction residual. products in the second pipe part is higher than that of the reaction residual products in the first pipe part.

7. The apparatus of claim 2, wherein a moving speed of reaction residual products in the second pipe part is higher than that of the reaction residual products in the first pipe part.

8. The apparatus of claim 1, further comprising a first member provided between the second pipe part and the liquid discharger and having a first face facing in a discharging direction of reaction residual products in the second pipe part.

9. The apparatus of claim 2, further comprising a first member provided between the second pipe part and the liquid discharger and having a first face facing in a discharging direction of reaction residual products in the second pipe part.

10. The apparatus of claim 9, wherein the first face of the first member is inclined in a gravity direction as approaching the liquid discharger.

11. The apparatus of claim 8, further comprising a mesh material provided on the first face of the first member.

12. The apparatus of claim 8, wherein the first face of the first member has grooves in a direction toward the liquid discharger.

13. The apparatus of claim 1, further comprising:
a third pipe part communicated with the second pipe part to pass above the liquid discharger and discharging an unliquefied part of the discharge gas; and
an adjuster provided in the third pipe part and adjusting a pressure in the film forming chamber, wherein
the second opening area is smaller than an opening area of the adjuster in a cross-section perpendicular to a discharging direction of the discharge gas.

14. The apparatus of claim 1, wherein the second opening area is equal to or smaller than 20% of the first opening area.

15. The apparatus of claim 1, wherein the second opening area is equal to or smaller than 10% of the first opening area.

16. The apparatus of claim 1, wherein the second opening area is between 2.5% and 20% of the first opening area.

17. The apparatus of claim 1, comprising:
a third pipe part communicated with the second pipe part to pass above the liquid discharger and discharging an unliquefied part of the discharge gas;
a fourth pipe part having one end connected between the first pipe part and the second pipe part and the other end connected to the third pipe part without via the second pipe part and the liquid discharger;
a first valve provided in the fourth pipe part; and
a second valve provided between the second pipe part and the third pipe part.

18. The apparatus of claim 17, wherein
the first valve is opened when a pressure in the film forming chamber is to be reduced and is closed when the discharge gas is to be discharged, and
the second valve is opened when the discharge gas is to be discharged.

19. The apparatus of claim 1, wherein
the second opening area is variable, and
the second opening area is a first area when a pressure in the film forming chamber is to be reduced and is a second area smaller than the first area when the discharge gas is to be discharged.

20. The apparatus of claim 2, wherein
the second opening area is variable, and
the second opening area is a first area when a pressure in the film forming chamber is to be reduced and is a second area smaller than the first area when the discharge gas is to be discharged.
